(19) United States
(12) Patent Application Publication
(10) Pub. No.: US 2010/0264488 A1
(43) Pub. Date: Oct. 21, 2010

(54) Low Qgd trench MOSFET integrated with schottky rectifier

(75) Inventor: FU-YUAN HSIEH, Kaohsiung (TW)

Correspondence Address: BACON & THOMAS, PLLC, 625 SLATERS LANE, FOURTH FLOOR, ALEXANDRIA, VA, 22314-1176, US

(73) Assignee: FORCE MOS TECHNOLOGY CO. LTD., Kaohsiung (TW)

(21) Appl. No.: 12/385,638

(22) Filed: Apr. 15, 2009

(51) Int. Cl. H01L 29/78; H01L 21/77

(52) U.S. Cl. 257/334; 438/270; 257/E29.257; 257/E21.598

(57) ABSTRACT

An integrated circuit includes a plurality of trench MOSFET and a plurality of trench Schottky rectifier. The integrated circuit further comprises: tilt-angle implanted body dopant regions surrounding a lower portion of all trench gates sidewalls for reducing Qgd; a source dopant region disposed below a bottom surface of all trench gates for functioning as a current path for preventing a resistance increased caused by the body dopant regions.

### BACKGROUND OF THE INVENTION

1. Field of the Invention

This invention relates generally to integrated circuits comprising power MOSFETs in parallel with Schottky rectifiers. More particularly, this invention relates to a novel and improved structure and improved process of fabricating an integrated trench MOSFET and Schottky rectifier with low charge between gate and drain (Qgd).

2. The Prior Arts

The Schottky barrier rectifiers have been used in DC-DC converters. In parallel with the parasitic PN body diode, the Schottky barrier rectifier acts as clamping diode to prevent the body diode from turning on for the reason of higher speed and efficiency, so the recent interests have been focused on the technology to integrate the MOSFET and the Schottky barrier rectifier on a single substrate. In U.S. patent application publication No. 6,351,018 and No. 6,593,620, methods of forming the Schottky rectifier on the same substrate with MOSFET are disclosed, as shown in FIG. 1 and FIG. 2, respectively.

In FIG. 1, an integrated trench MOSFET-Schottky rectifier structure is fabricated on an N substrate 102, into which a plurality of trenches 100 are etched. A thin layer of insulator 104 lines the sidewalls of the trenches 100 which are refilled with conductive material 106 to act as gate material. Well regions 108 of a second doping type, e.g., P dopant, are formed by diffusion between every two trenches except those where Schottky rectifier will be formed (trench 100-3 and 100-4, as illustrated). Near the top surface of every well region, source regions 112 are introduced followed by the formation of P+ body region 114 between every two adjacent source regions within each well region. In order to distinguish the conductive layers player different roles, 116 is marked to figure those layers connecting to source regions while 118 figures the anode of Schottky rectifier 110 as shown. And metal layer 120 is deposited to short the source regions 212 and the anode of Schottky rectifier 110.

In FIG. 2, another combination structure is illustrated, which has DMOS transistor devices within DMOS transistor region 220 and has Schottky barrier rectifier devices within rectifier region 222. The combination structure further comprises: a substrate 200 heavily doped with a first semiconductor type dopant, e.g., N+ dopant, on which an epitaxial layer 202 lightly doped with the same semiconductor type dopant as substrate is grown, serving as drain for the DMOS transistor devices and cathode region for the Schottky rectifier devices; metal layer 218 coated on the rear side of the substrate to act as a common drain contact for DMOS transistors and a common cathode electrode for the Schottky rectifiers; metal layer 216 deposited on the front side of the substrate to act as a common source contact for the DMOS transistor devices and as common anode electrode for the Schottky rectifier devices; trench regions lined with oxide layer 206 and filled with polysilicon 210 to serve as trench gates; BPSG layer 214 covering each trench gate to insulate the polysilicon 210 from conductive layer 216 for the DMOS transistors; body regions 204 of a second semiconductor doping type, e.g., P dopant, are formed between every two trench gates in DMOS transistors portion; source region 212 heavily doped with said first semiconductor doping type adjacent the sidewalls of trench gates near the top surface of said body region. It should be noticed that, the Schottky barrier rectifiers and the DMOS transistors in this structure have separated trench gates in contrast to the structure mentioned in FIG. 1.

Though both structures in prior arts introduced can achieve the integration of MOSFET devices and Schottky barrier rectifiers on a single substrate, there are still some disadvantages affecting the performances of whole device.

First of all, in order to further increase the switching speed of a semiconductor power device, it is desirable to reduce the coupling charges between the gates and drain Qgd such that a reduction of a gate to drain capacitance Crss can be achieved. However, conventional devices shown in FIG. 1 and FIG. 2 each has a large amount of coupling charges Qgd between gates and drain due to the direct coupling between the trench bottoms and portion of trench sidewalls and the drift region.

Another disadvantage of the prior art is that, the planar contact employed occupies a large area, almost one time of MOSFET. As the size of devices is developed to be smaller and smaller, this planar contact structure is obviously should replaced by another configuration which will meet the need for size requirement. On the other hand, this kind of planar structure will lead to a device shrinkage limitation since the contacts occupy a large area, resulting in high specific on-resistance according to the length dependence of resistance.

Another disadvantage of prior art is that, during fabricating process, an additional P+mask or contact mask for opening of Schottky rectifier anode contact is required, therefore increases the fabrication cost.

Accordingly, it would be desirable to provide an integrated trench MOSFET-Schottky rectifier structure having lower Qgd, lower on-resistance, and, at the same time, having smaller device area with lower fabrication cost.

### SUMMARY OF THE INVENTION

It is therefore an object of the present invention to provide new and improved integrated trench MOSFET-Schottky rectifier device and manufacture process solving the problems mentioned above.

One advantage of the present invention is that, doping regions of a second semiconductor doping type, e.g., P dopant, marked by p* regions as shown in FIGS. 3 to 6, are formed surrounding the lower portions of trench gate sidewalls to decouple trench gates from the drain such that the coupling charges between trench gates and the drain can be reduced. Furthermore, doping regions of a first semiconductor doping type, e.g., N dopant, marked by n* regions as shown in FIGS. 3 to 6, are formed right below the trench bottoms to provide a current path between the drain to the source such that the decoupling p* regions will not inadvertently increase the resistance between the drain and source but Crss can be significantly reduced to a value that is about half or even lower when compared with the capacitance of the conventional devices because the Crss (Capacitance between gate and drain) or Qgd will be mainly determined by trench width in the present invention when compared with the conventional devices as shown in FIG. 1 and FIG. 2.

Another advantage of the present invention is that, the planar contact for both MOSFET devices and Schottky rectifier are replaced by trench contact structure. By employing this trench contact, the devices are able to be shrunk to achieve low specific on-resistance for trench MOSFET, and, at the same time, achieve low Vf (forward voltage) and low Ir (reverse leakage current) for Schottky rectifier.

Another advantage of the present invention is that, there's no need to use additional mask to open the anode of Schottky rectifier in fabricating process according to this invention, therefore cost saving is achieved.

Briefly, in a preferred embodiment, as shown in FIG. 3, the present invention disclosed an integrated device cell formed on a heavily doped substrate of a first semiconductor doping type comprising: a trench MOSFET and a trench Schottky rectifier. Said trench MOSFET further comprises: trench gates filled with doped poly above a layer of gate oxide and surrounded by a source region of first semiconductor doping type encompassed in a body region of second semiconductor doping type above a drain region disposed on the bottom surface of said substrate; tilt-angle implanted regions of the opposite dopant type to substrate surrounding the lower portions of trench gates sidewalls to further reduce Qgd; doping regions of the same dopant type as the substrate right below trench gate bottoms for functioning as a current path between the drain to the source for preventing a resistance increase caused by the doping regions surrounding the lower portions of the trench gates sidewalls; trench contacts penetrating a thick oxide layer and filled with tungsten plugs padded with barrier layer of Ti/TiN or Co/TiN to connect all the source regions to source metal of Al alloys or Copper deposited onto a resistance-reduction layer of Ti or Ti/TiN; P+ regions at the bottom of each contact trench to further reduce contact resistance;. The trench Schottky rectifier further comprises: trench gates filled with doped poly and penetrating into epitaxial layer built on said substrate; tilt-angle doping regions of the opposite dopant type to the substrate surrounding the sidewalls of trench gates; doping regions of the same dopant type as the substrate right below trench gate bottoms; contact trenches with a layer of Ti/TiN or Co/TiN lining the inner surface; P+regions at the bottom of each contact trench except trenches penetrating into trench gates introduced in the same step with those of trench MOSFET; tungsten plug filled into each the contact trench as anode material for trench Schottky and connected to metal layer of Al alloys or Copper which is the same metal layer as source metal for trench MOSFET. What should be noticed is that, according to this preferred embodiment, the integrated structure has single gate oxide and the trench gates in Schottky rectifier is not connected with trench gates in trench MOSFET but shorted with anode of Schottky rectifier.

Briefly, in another preferred embodiment, as shown in FIG. 4, the structure disclosed is similar to that shown in FIG. 3 except that, there is no P+ region underneath each contact trench in trench Schottky rectifier by using additional P+ mask to block P+ Ion Implantation during fabricating process. [00016] Briefly, in another embodiment, the present invention disclosed an integrated structure formed on a heavily doped substrate of a first semiconductor doping type comprising a trench MOSFET and a trench Schottky rectifier and in parallel with a trench gate portion. Said trench MOSFET further comprises: trench gates filled with doped poly above a layer of gate oxide and surrounded by a source region of the first semiconductor doping type encompassed in a body region of the second semiconductor doping type above a drain region disposed on bottom surface of said substrate; tilt-angle implanted regions of the opposite dopant type to substrate surrounding the lower portions of trench gate sidewalls to further reduce Qgd; doping regions of the same dopant type as the substrate right below trench gate bottoms for functioning as a current path between the drain to the source for preventing a resistance increase caused by the doping regions surrounding the lower portions of the trench gates sidewalls; trench contacts penetrating a thick oxide layer and filled with tungsten plugs padded with layer of Ti/TiN or Co/TiN to connect all the source regions to source metal of Al alloys or Copper deposited onto a resistance-reduction layer of Ti or Ti/TiN; P+ regions at the bottom of each contact trench to further reduce contact resistance. The trench Schottky rectifier further comprises: trench gates filled with doped poly and penetrating epitaxial layer built on said substrate; doping regions of the opposite dopant type to the substrate surrounding the sidewalls of trench gates; doping regions of the same dopant type as the substrate right below trench gate bottoms; contact trenches with a layer of Ti/TiN or Co/TiN lining the inner surface; P+ regions at the bottom of each contact trench introduced in the same step as those of trench MOSFET; tungsten plug filled into each the contact trench as anode material for trench Schottky and connected to metal layer of Al alloys or Copper which is the same metal layer as source metal for trench MOSFET. What should be noticed is that, according to this preferred embodiment, the trench gate in Schottky rectifier introduced in not shorted with anode via trench contact like the first embodiment, and trench MOSFET and trench Schottky rectifier have common trench gate.

Briefly, in another preferred embodiment, as shown in FIG. 6, the structure disclosed is similar to that shown in FIG. 5 except that, there is no P+ region underneath each contact trench in trench Schottky rectifier by using additional P+ mask to block P+ Ion Implantation during fabricating process.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a side cross-sectional view of an integrated trench MOSFET and Schottky rectifier of prior art.

FIG. 2 is a side cross-sectional view of another integrated trench MOSFET and Schottky rectifier of prior art.

FIG. 3 is a side cross-sectional view of a preferred embodiment in accordance with the present invention.

FIG. 4 is a side cross-sectional view of another preferred embodiment in accordance with the present invention.

FIG. 5 is a side cross-sectional view of another preferred embodiment in accordance with the present invention.

FIG. 6 is a side cross-sectional view of another preferred embodiment in accordance with the present invention.

FIGS. 7A to 7E are a serial of side cross-sectional views for showing the processing steps for fabricating integrated trench MOSFET and Schottky rectifier in FIG. 4.

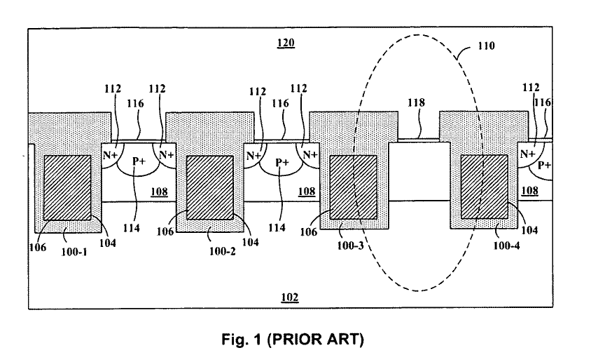

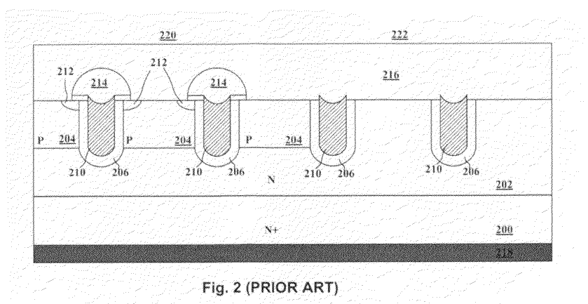

### DETAILED DESCRIPTION OF THE EMBODIMENTS

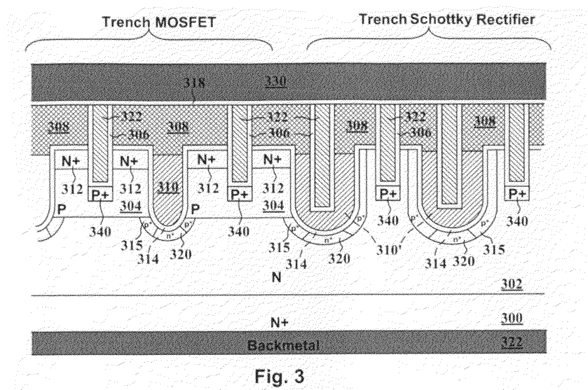

Please refer to FIG. 3 for a preferred embodiment of the present invention where an integrated trench MOSFET and Schottky rectifier is formed on a heavily N+ doped substrate 300 with back metal 322 on rear side as drain. Onto said substrate, an epitaxial layer 302 of the same doping type as substrate and lighter concentration is grown. The disclosed structure further comprises a plurality of trench gates 310 for trench MOSFET and a plurality of wider trench gates 310′ for Schottky rectifier, where trench gates 310 and 310′ all filled with doped poly padded by a single gate oxide layer 314 along the inner surface of gate trenches. A plurality of P body regions 304 extend between trench gates on the upper portion of the epitaxial layer 302 except between those for Schottky rectifier. The body regions 304 further encompassed source regions 312 formed near the top surface of the epitaxial layer 302. A thick oxide insulation layer 308 covering the top surface of epitaxial layer with contact trench opened and filled with tungsten plug 322 over a barrier layer 306 of Ti/TiN or Co/TiN for trench MOSFET and Schottky rectifier, respectively. Right below each trench contact except those for Schottky rectifier gate connection, a P+ region 340 is formed to reduce the resistance between metal plug 322 and body region 304 to allow a low-resistance contact for trench MOSFET portion. In Schottky rectifier portion, trench contacts are used to form Schottky diodes along trench contact sidewalls after the formation of layer 306 along each trench. Above the thick oxide layer 308, metal layer 330 composed of Al alloys or Copper coated with a resistance reduction layer 318 composed of Ti or Ti/TiN is deposited to be electrically connected to source regions 312 and body regions 304 of trench MOSFET while functioning as anode metal for Schottky rectifier. Especially, the trench gates in Schottky rectifier is not connected with then trench gates in trench MOSFET but shorted with anode of Schottky rectifier.

For the purpose of reducing the Qgd, the sidewalls of trench gates for Schottky rectifier and bottom portion of the sidewalls of trench gates for trench MOSFET are surrounded by P-dopant regions 315, as marked by p* in FIG. 3. Furthermore, the central portions underneath the bottom of all trench gates are formed with N doped regions 320, as marked by n* in FIG. 3 below each trench gate. The Qgd is reduced with the p* dopant regions 315 while the n* dopant regions 320 under the trench bottom provide a current path of drain to source thus prevent the inadvertent increase of the resistance. Furthermore, by reducing the Qgd, the capacitance Crss may be reduced to half of the original capacitance or even lower compared to the capacitance of the conventional devices.

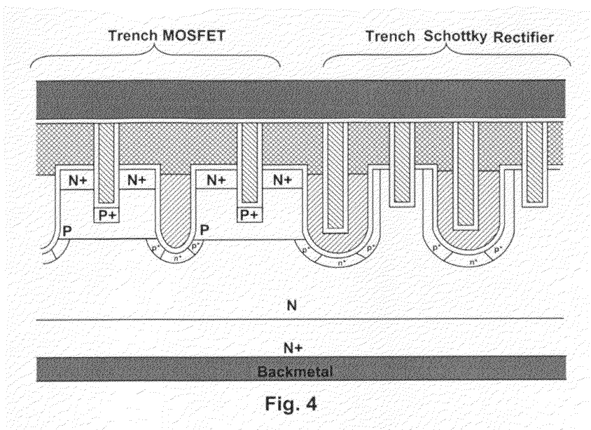

FIG. 4 shows a side cross sectional view of another preferred embodiment of the present invention with a similar configuration to that of structure shown in FIG. 3. The only difference is that, there is no P+ area underneath trench contacts for Schottky rectifier, which implemented by using additional P+ mask to block P+ Ion Implantation during fabricating process.

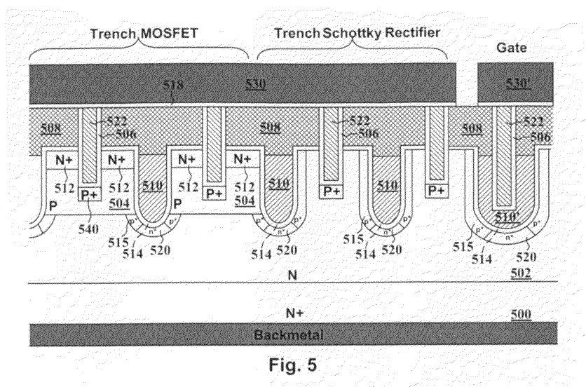

Please refer to FIG. 5 for another preferred embodiment of the present invention which is built in an N doped epitaxial layer 502 onto an N+ doped substrate 500. A plurality of trenches and at least a wider trench for gate connection are etched into said epitaxial layer and are filled with doped poly padded with a layer of gate oxide 514 to form trench gates 510 and at least a common trench gate 510′ for both trench MOSFET and Schottky rectifier. P body regions 504 are extending between two adjacent trench gates 510 with source regions 512 near its upper surface. Source-body contact trenches and at least a gate contact trench with P+ contact area 540 whereunder are opened through thick oxide interlayer 508 and into P-body regions and trench gate for gate connection, respectively. Above a barrier layer 506 composed of Ti/TiN or Co/TiN, tungsten plugs 522 are filled into contact trenches to form source-body contact and gate contact, respectively. Metal layer composed of Al alloys or Copper coated with a resistance reduction layer 518 composed of Ti or Ti/TiN is deposited and patterned by metal mask to form metal layer 530 and 530′. Specifically, metal layer 530 contacts the source and body regions of Trench MOSFET with the anode of Schottky rectifier, while metal 530′ is connected to the common trench gate, which means the trench gate in Schottky rectifier is not shorted with anode via trench contact like the first embodiment. For the purpose of reducing the Qgd, the sidewalls of trench gates for Schottky rectifier and bottom portion of the sidewalls of trench gates for trench MOSFET are surrounded by P-dopant regions 515 and the central portions underneath the bottom of all trench gates are formed with N doped regions 520.

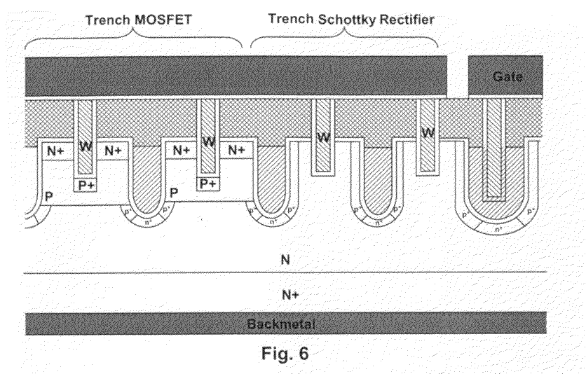

FIG. 6 shows a side cross sectional view of another preferred embodiment of the present invention with a similar configuration to that of structure shown in FIG. 5. The only difference is that, there is no P+ area underneath trench contacts for Schottky rectifier, which implemented by using additional P+ mask to block P+ Ion Implantation during fabricating process.

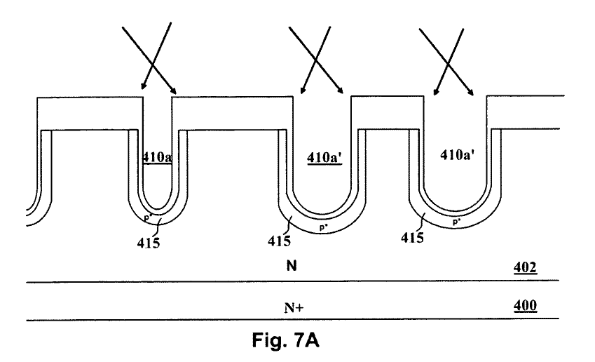

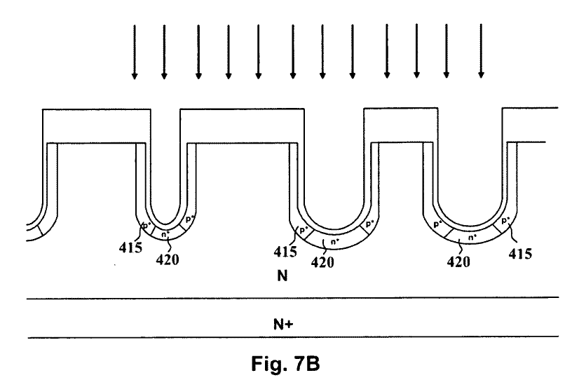

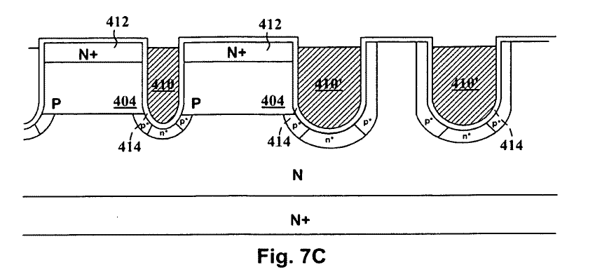

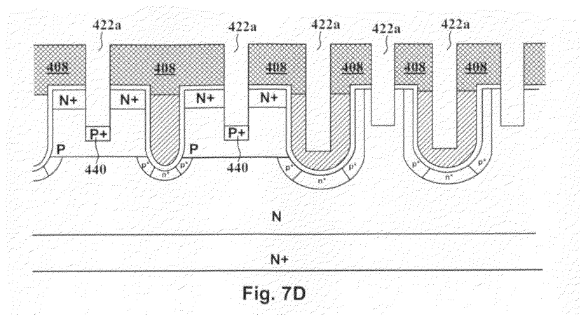

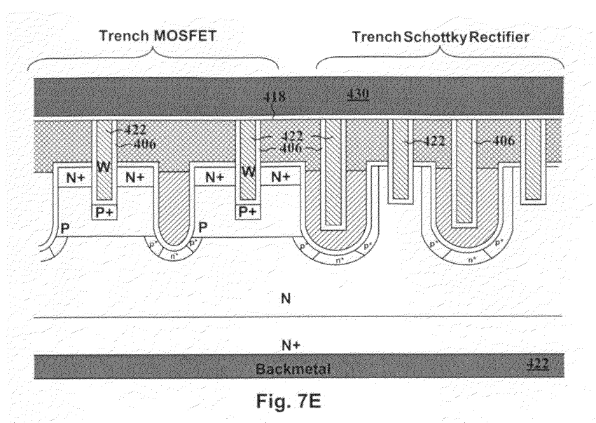

In FIG. 7A, an N doped epitaxial layer 402 is grown on an N+ substrate 400, then, after a thick oxide deposition along top surface of the epitaxial layer 402, a trench mask (not shown) is applied, which is then conventional exposed and patterned to leave mask portions. The patterned mask portions define the gate trenches 410a for trench MOSFET and 410′ for Schottky rectifier, which are dry oxide etched and dry silicon etched through mask opening to a certain depth. Next, a sacrificial oxide (not shown) is grown and then removed to eliminate the plasma damage may introduced during trenches etching process. After that, a screen oxide is grown for the followed Boron angle Ion Implantation to form p* areas 415 wrapping the sidewalls and bottoms of gate trenches 410a and 410a′.

In FIG. 7B, another vertical Arsenic or Phosphorus Ion Implantation is carried out to form n* area 420 right below the gate trenches 410a and 410a′. In FIG. 7C, screen oxide is first removed and gate oxide layer 414 is formed on the front surface of epitaxial layer 402 and the inner surface of gate trenches 410a and 410a′. Next, all gate trenches are filled with doped poly to form trench gates 410 for trench MOSFET and trench gates 410′ for Schottky rectifier. Then, the filling-in conductive material such as doped poly is etched back or CMP (Chemical Mechanical Polishing) to expose the portion of gate oxide layer that extends over the surface of epitaxial layer. Next, by employing a P-body mask, an Ion Implantation is applied to form P-body regions 404, followed by a P-body diffusion step for P-body region drive in. After removing the P-body mask, another Ion Implantation is applied to form N+ source regions 412 using a source mask followed by an n+ diffusion step for source regions drive in. Then, in FIG. 7D, a thick oxide interlayer 408 is formed over whole top surface, through which contact trenches 422a are etched by forming a contact mask (not shown) by successive dry oxide etching and dry silicon etching. Next, the BF2 Ion Implantation is applied over contact area mask to form the P+ area wrapping the bottom of contact trenches in trench MOSFET portion to further reduce contact resistance. In FIG. 7E, after the deposition of Ti/TiN or Co/TiN layer 406, a step of RTA (Rapid Thermal Annealing) under 730˜900° C. for 30 seconds is carried out for the formation of TiSi₂ or CoSi₂. Then, all contact trenches are filled with W metal 422 to form trench contacts for trench MOSFET and Schottky rectifier. After the Ti/TiN/W or Co/TiN/W etching back, Al Alloys or copper metal layer is deposited over a resistance reduction layer 418 composed of a low resistance metal layer such as a Ti or Ti/TiN layer to serve as front metal 430. Last, Drain metal 422 composed of Ti/Ni/Ag is then deposited on rear surface after backside grinding.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. An integrated circuit comprising a plurality of trench MOSFET and a plurality of trench Schottky rectifier further comprising:
a substrate of the first conductivity type;
an epitaxial layer of said first conductivity type over said substrate, said epitaxial layer having a lower doping concentration than said substrate;
a trench MOSFET comprising a trenched gate surrounded by a source region of said first conductivity type encompassed in a body region of second conductivity type above a drain region disposed on a bottom surface of a substrate;
a trench Schottky rectifier extending into said epitaxial layer and having a Schottky barrier layer lined in trench contact filled with contact metal plug;
a plurality of doped polysilicon filled within said gate trenches padded with a layer of gate oxide;
a plurality of tile-angle implanted body dopant regions surrounding a lower portion of trench sidewalls for reducing a gate-to-drain coupling charges Qgd;
a source dopant region disposed below a bottom surface of said trench gates for functioning as a current path between said drain to said source for preventing a resistance increase caused by said body dopant regions surrounding said lower portions of said trench sidewalls;
an insulation layer covering said integrity circuit with trench contacts filled with metal plug padded with barrier layer penetrating therethrough and extending into said epitaxial layer.

2. The MOSFET of claim 1 wherein said trench gates of said trench MOSFET is separated from trench Schottky rectifier which is shorted with anode of said trench Schottky rectifier.

3. The MOSFET of claim 1 wherein said trench MOSFET and said trench Schottky rectifier have common trench gates which are connected each other.

4. The MOSFET of claim 1 wherein said gate oxide is single gate oxide.

5. The MOSFET of claim 1 wherein said barrier layer lines said contact trench is Ti/TiN or Co/TiN.

6. The MOSFET of claim 1 wherein said contact metal plug overlying the barrier layers is tungsten.

7. The MOSFET of claim 1 wherein said Schottky barrier comprises TiSi2 (Ti Silicide) or CoSi2 (Co Silicide).

8. The MOSFET of claim 1 wherein the source/anode metal is Ti/Aluminum alloys, Ti/TiN/Aluminum alloys, or Ti/TiN/Copper.

9. The MOSFET of claim 1 wherein said Schottky barrier lines along contact trench sidewall and bottom, or only sidewall.

10. A method for manufacturing an integrated circuit comprising a plurality of N-channel trench MOSFET and a plurality of trench Schottky rectifier further comprising the steps of:
growing an epitaxial layer upon a heavily N doped substrate, wherein said epitaxial layer is doped with N dopant;
depositing a layer of oxide onto said epitaxial layer as hard mask;
forming a trench mask with open and closed areas on the surface of said epitaxial layer;
removing semiconductor material from exposed areas of said trench mask to form a plurality of gate trenches;
growing a sacrificial oxide layer onto the surface of said trenches to remove the plasma damage introduced during opening said trenches;
removing said sacrificial oxide and growing a layer of screen oxide;
forming body doped regions by tile-angle Boron Ion Implantation;
forming source doped regions by vertical Arsenic or Phosphorus Implantation;
removing said screen oxide and said hard mask, and forming a first insulating layer on the surface of said epitaxial layer and along the inner surface of said gate trenches as gate oxide;
depositing doped poly onto said gate oxide and into said gate trenches;
etching back or CMP said doped poly to leave portions within gate trenches;
forming a body mask and implanting said epitaxial layer with a second type dopant to from P-body regions;
removing said body mask and forming a source mask;
implanting whole device with a first type dopant to form source regions and removing said source mask;
forming a second insulating layer onto whole surface as contact interlayer;
forming a contact mask on the surface of said second insulating layer and removing the insulating material and semiconductor material;
implanting BF2 ion to form P+ area wrapping bottom of source-body contact trench within P-body region;
depositing Ti/TiN or Co/TiN into contact trenches as barrier layer and on the front surface and continues with RTA step under 730˜900° C. for 30 seconds;
depositing metal plugs into contact trenches and etching back barrier layer and metal plugs;
depositing a layer of Ti or Ti/TiN as resistance-reduction layer onto the contact interlayer;
depositing a layer of Al alloys or Copper on the front and rear side of device, respectively.

11. The method of claim 10, wherein forming said gate trenches comprises etching said doped poly according to the open areas of said trench mask by successively dry oxide etching and dry poly etching.

12. The method of claim 10, wherein forming said P-body regions comprises a step of diffusion to achieve a certain depth after P-body implantation step.

13. The method of claim 10, wherein forming said source regions comprises a step of diffusion to achieve a certain depth after n+ Ion Implantation step.

14. The method of claim 10, wherein forming said contact trench comprises etching through said N+ source regions and into said P-body regions by dry silicon etching for the formation of source-body contact trench; and etching into gate filling-in material for the formation of gate contact trench;
